(19) United States
(12) Patent Application Publication
(10) Pub. No.: US 2003/0128507 A1
(43) Pub. Date: Jul. 10, 2003

(54) Mobile wireless data and electrical power unit

(76) Inventor: Keith E. Metcalf, Jasper, IN (US)

Correspondence Address: BAKER & DANIELS, 111 E. WAYNE STREET, SUITE 800, FORT WAYNE, IN, 46802

(21) Appl. No.: 10/313,047

(22) Filed: Dec. 6, 2002

Related U.S. Application Data
(60) Provisional application No. 60/339,713, filed on Dec. 6, 2001.

(51) Int. Cl. H05K 5/00

(52) U.S. Cl. 361/686

(57) ABSTRACT

A portable data and electrical power unit, including a moveable housing having at least one electrical receptacle and at least one data receptacle accessible from the exterior of the housing, at least one rechargeable power source disposed in the housing with the electrical receptacle receiving electrical power from the rechargeable power source, at least one data transfer device mounted in the housing and in communication with the data receptacle, and at least one external peripheral device connected to at least one of the electrical receptacle and the data receptacle.

### CROSS REFERENCE TO RELATED APPLICATIONS

This application claims the benefit under Title 35, U.S.C. § 119(e) of U.S. Provisional Patent Application Serial No. 60/339,713, entitled MOBILE AND WIRELESS DATA AND ELECTRICAL POWER UNIT, filed on Dec. 6, 2001.

### BACKGROUND OF THE INVENTION

1. Field of Invention

The present invention relates to electrical and data services units, specifically, electrical and data services units which are mobile and may be used in a variety of locations.

2. Description of the Related Art

The use of mobile electrical power units in association with other devices, such as laptop computers, printers, and other computer related peripheral devices is known. However, many such power units rely on a continuous external power source to supply power to the computer and the various peripheral devices, which limits the use of such units to areas having easily accessible electrical receptacles.

Another problem with the above-described known mobile units is that many such units provide only electrical power to the computer and/or various peripheral devices. Merely supplying power to the computer and other electronic peripheral devices disadvantageously limits the peripheral devices to accessing the information and data maintained within the devices themselves.

Some known units supply limited data transfer capabilities in addition to power. Such units provide multiple data access points or other data connectors and a network hub, which may be connected to local area network adapters to provide data transfer capabilities between the connected peripheral devices. However, these units still rely on continuous external alternating current (AC) power sources for supplying power to the peripheral devices. Like other known units, these units are limited to use in locations where electrical receptacles or power supplies are accessible, thereby limiting the usefulness of the units.

What is needed is a mobile data and electrical power unit which is an improvement over the foregoing.

### SUMMARY OF THE INVENTION

The present invention provides a mobile data and electrical power unit which supplies power to one or more computers and/or various other peripheral and handheld devices, and also provides data connections for such devices. Furthermore, the present mobile data and electrical power unit is totally self-contained with respect to its power supply and data transfer capabilities, thereby eliminating the need for a continuous external power source or an external data connection.

By being self-contained, the mobile data and electrical power unit may be used at any location, whether external electrical power sources and data connections are available or not, thus the unit is not limited to locations where it can be plugged into an electrical receptacle to receive power. Furthermore, through the inclusion of a data network within the self-contained unit, several computers and devices may simultaneously connect to the cabled or wireless data ports in the unit and use the data network to transfer data in addition to being powered by the unit. Alternatively, if the devices include internal power sources, the devices may use the unit as common data connection and exchange point without receiving power from the unit. The unit may also be connected to a wide area network (“WAN”), such as the Internet, and therefore serve as a gateway for associated computers and devices.

In one form thereof, the present invention provides a portable data and electrical power unit, including a moveable housing having at least one electrical receptacle and at least one data receptacle accessible from the exterior of the housing; at least one rechargeable DC power source disposed in the housing, the electrical receptacle receiving electrical power from the rechargeable DC power source; and at least one data transfer device mounted in the housing and in communication with the data receptacle.

In another form thereof, the present invention provides a portable data and electrical power unit, including a movable housing having an exterior wall; a handle connected to the housing; at least one electrical receptacle and at least one data receptacle mounted within the exterior wall and accessible from the exterior of the housing; at least one rechargeable power source disposed within the housing, the rechargeable power source electrically connected to each electrical receptacle to supply electrical power thereto; and at least one data transfer device disposed within the housing, the data transfer device in communication with the data receptacle.

### BRIEF DESCRIPTION OF THE DRAWINGS

The above-mentioned and other features and advantages of this invention, and the manner of attaining them, will become more apparent and the invention itself will be better understood by reference to the following description of embodiments of the invention taken in conjunction with the accompanying drawings, wherein:

FIG. 1 is a front perspective view of a first embodiment of a mobile data and electrical power unit in accordance with the present invention;

FIG. 1A is an enlarged view of a portion of the front of the unit of FIG. 1 showing alternating current (AC) electrical outlets disposed within a recessed portion of the unit;

FIG. 1B is an enlarged view of a portion of the front of the unit of FIG. 1 showing data ports disposed within a recessed portion of the unit;

FIG. 1C is an enlarged view of a portion of the front of the unit of FIG. 1 showing universal serial bus (USB) ports disposed within a recessed portion of the unit;

FIG. 1D is an enlarged view of a modified portion of the front of the unit of FIG. 1 showing direct current (DC) electrical outlets disposed within a recessed portion of the unit;

FIG. 2 is a schematic block diagram of the electrical power supply circuit within the unit;

FIG. 3 is a perspective view of the unit in a schematic mobile office setting, showing the unit connected to several external devices;

FIG. 4 is a schematic block diagram of a data network provided by the unit;

FIG. 5 is a rear cutaway perspective view of the unit of FIG. 1, showing various internal power devices;

FIG. 6 is a perspective view of a second exemplary embodiment of a mobile data and electrical power unit in accordance with the present invention; and

FIG. 7 is a perspective view of a third exemplary embodiment of a mobile data and electrical power unit in accordance with the present invention.

Corresponding reference characters indicate corresponding parts throughout the several views. The exemplifications set out herein illustrate embodiments of the invention and such exemplifications are not to be construed as limiting the scope of the invention in any manner.

### DETAILED DESCRIPTION

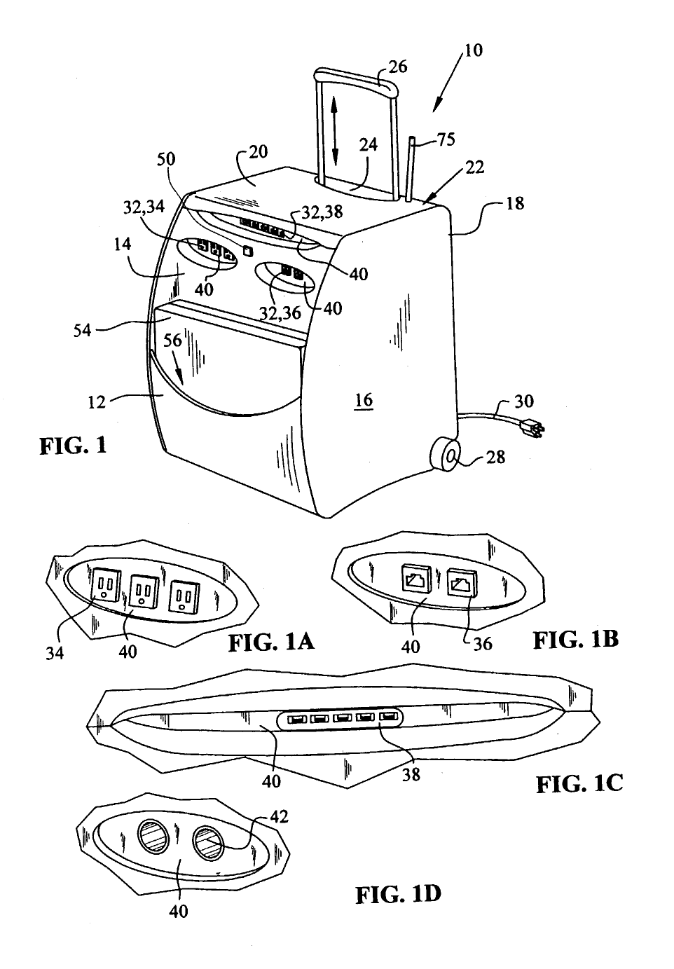

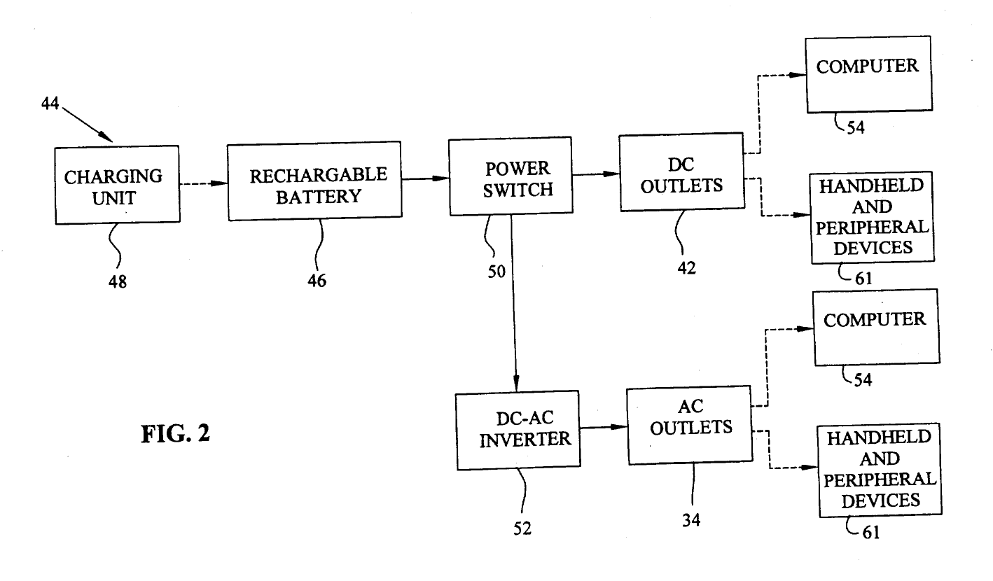

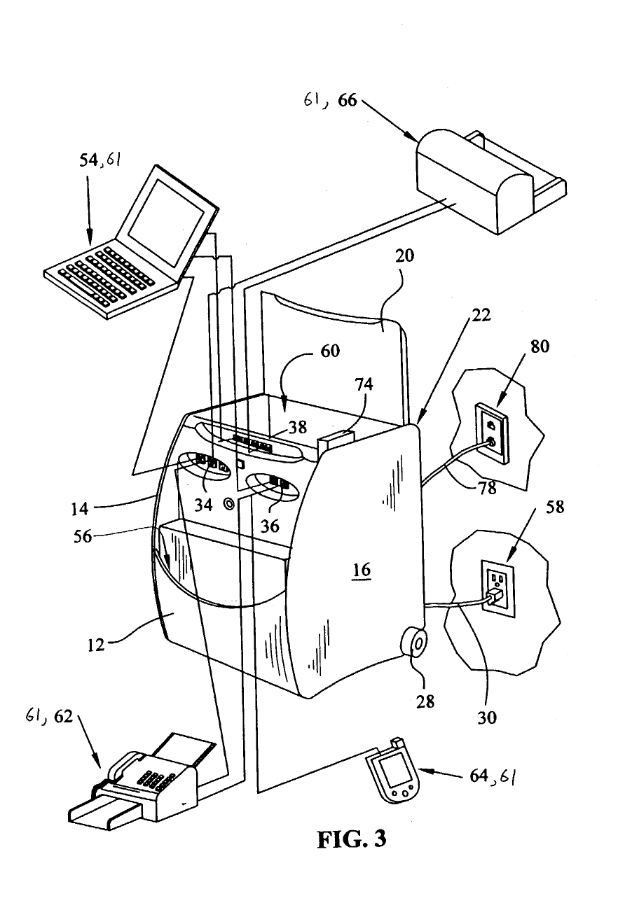

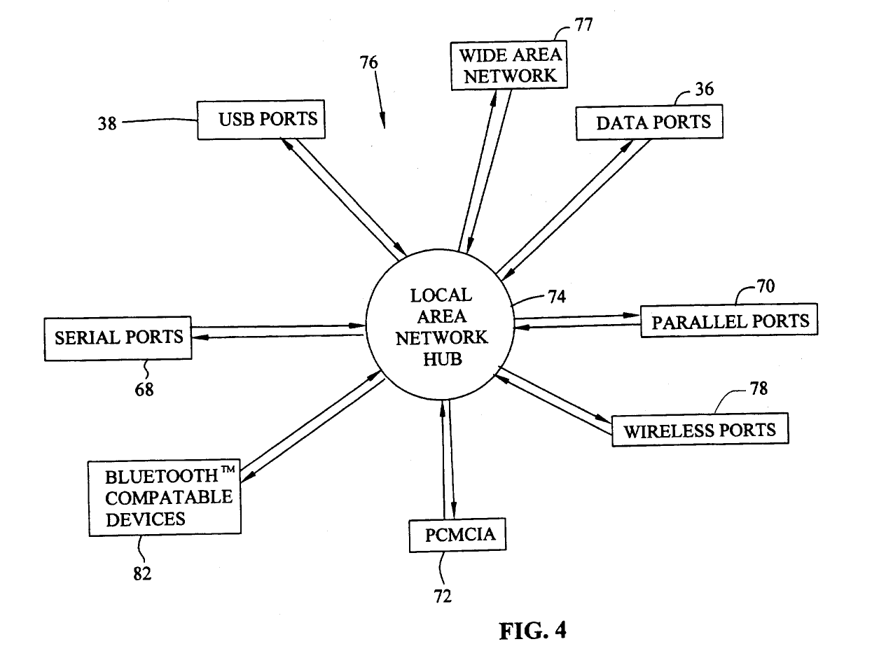

Referring to FIG. 1, a first exemplary embodiment of mobile data and electrical power unit 10 generally includes wheeled cabinet 22 having a series of data and electrical receptacles 32 mounted within front faceplate 14. FIG. 2 shows a schematic block diagram of power components housed within cabinet 22, including rechargeable battery 46 which provides a power source for computers 54 and other devices 61 that may be associated with unit 10, for example, fax machine 62 and printer 66 as shown in FIG. 3. FIG. 4 shows a schematic block diagram of data network 76 provided by unit 10, including local area network (“LAN”) hub 74 and various data connection ports and protocols 36, 38, 70, 72, 78, and 82 that may be used for data communication between associated computers 54 and devices 61 and LAN hub 74. Additionally, LAN hub 74 may serve as a gateway to a wide area network (“WAN 77”), such as the Internet.

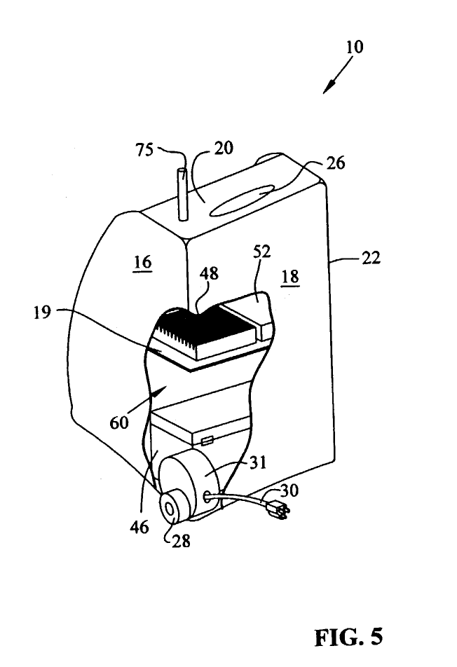

As described further below, unit 10 is self-contained, with a power source and data network contained within the unit, such that unit 10 may be used to supply electrical power and data services in a variety of locations, such as airports, conference rooms, convention halls, training rooms, outdoors, in automobiles, and any other location where electrical receptacles and data connections are not easily accessible. Unit 10 is compact and mobile, and may be moved about on wheels 28 thereof from place to place in a manner similar to pulling a rolling piece of luggage. Retractable handle 26 extends vertically from opening 24 in lid 20, as shown in FIG. 1, for grasping by a user to move unit 10 about. When unit 10 is not in use, handle 26 may be returned to its retracted, stowed position, as shown in FIG. 5.

Referring again to FIG. 1, a first exemplary embodiment of mobile data and electrical power unit 10 is shown, including cabinet 22 with front wall 12 having front faceplate 14, side walls 16, back wall 18, and lid 20 hingedly mounted to unit 10. Retractable handle 26 of unit 10, described above, may extend from opening 24 in lid 20, and wheels 28 are mounted along the rear bottom of each side wall 16 of unit 10. Front wall 12 of unit 10 further includes integral pocket 56 defined between front wall 12 and faceplate 14 (FIG. 1) into which laptop computer 54, or other devices or materials, may be stowed.

Located in the upper portion of front wall 12 is front faceplate 14 having a plurality of recessed portions 40 in which at least one data or electrical receptacle 32 may be mounted. Data and electrical receptacles 32 are selectively interchangeable with one another, such that each unit 10 may be configured with a different combination of various types of data and electrical receptacles 32, depending upon the particular needs of the user of unit 10. Thus, data and electrical receptacles 32 in each recessed portion 40 may be one or more AC electrical outlets 34 (FIG. 1A); data ports 36 (FIG. 1B) typically used for LAN data connections such as Universal Serial Bus (“USB”) ports or other data protocol connections 38 (FIG. 1C); 12 volt DC outlets 42 (FIG. 1D); or any combination thereof. However, data and electrical receptacles 32 may also include any other type of releasable data and power connector as is known in the art.

As shown in FIGS. 1, 3, and 5, unit 10 may also include retractable electrical cord 30, extending from cord retracting unit 31 (FIG. 5) through back wall 18. Electrical cord 30 may be plugged into a conventional wall outlet 58 (FIG. 3) for recharging an internal power source, such as battery 46 (FIGS. 2 and 5), which is located within unit 10. Electrical cord 30 may be used to provide power to external devices which are connected to unit 10 when unit 10 is used in an area in which an external electrical power source is available. However, electrical cord 30 may also conduct power from an external power source in order to recharge battery 46, such that battery 46 provides power to devices which are connected to unit 10 in areas where external electrical power sources are unavailable.

Referring now to FIG. 2, a schematic block diagram of electrical circuit 44 is shown. Unit 10 provides electrical power through the use of at least one battery 46, which may be recharged by charger 48. Although the term “battery” has been used in its singular form, unit 10 may use one battery 46 or a power source including a plurality of electrically connected individual batteries 46, depending upon the requirements of the user. Battery 46 may be a sealed lead acid battery such as Part No. X512-200 manufactured by Xantrex Technology of Arlington, Wash.; a nickel-cadmium (“Ni-Cad”) battery such as the VN Series available from ALCAD of North Haven, Conn., or other rechargeable batteries known in the art. Alternatively, another form of self-contained power source may provide power for unit 10, for example, fuel cells.

Battery 46 is located within interior compartment 60 of unit 10, as shown in FIG. 5. By utilizing rechargeable battery 46, power is provided to electrical outlets 34 and 42 without a continuous external power source, thus providing power for computer 54, handheld and peripheral devices 61, or other data appliances.

Referring to FIG. 2, in the first exemplary embodiment, battery 46 provides 12 volts DC which may be used to supply DC outlets 42, if included in unit 10, when power switch 50 is closed. DC outlets 42 may be standard automobile cigarette lighter-type outlets, or another standard DC power outlet, such as those typically used for handheld and peripheral devices 61. Power circuit 44 may also provide a different DC voltage to DC outlets 42, for example, 6 volts or 9 volts.

When switch 50 is closed, battery 46 also supplies DC power to DC-to-AC power inverter 52. Inverter 52 supplies AC power to AC outlets 34, which may be mounted in recessed portions 40 on the exterior of unit 10 in place of, or in addition to, DC outlets 42. As shown in FIG. 5, inverter unit 52 is also mounted within interior compartment 60 of housing 22, for example, secured to support shelf 19. Inverter 52 may be selected to provide the particular type of AC power that is available in the region in which unit 10 is to be used, for example, 110 volts or 220 volts, and 50 hertz or 60 hertz. An exemplary DC to AC inverter is Part No. PROWATT 250, manufactured by Fedco Electronics, Inc., of Fond Du Lac, Wis.

Charging unit 48, as shown in FIGS. 2 and 5, is connected to rechargeable battery 46 and may be used to periodically recharge battery 46. Charging unit 48 is also located within interior compartment 60 of cabinet 22, such as on support shelf 19 as shown in FIG. 5. Charging unit 48 is of the type that receives the commonly available external power, for example, 110 V AC, and provides quick DC recharging of battery 46. An exemplary charging unit is Part No. 80-0100 manufactured by Xantrex Technology, Inc. Alternatively, other type charging units could be used, for example, a solar collector charging unit, or a charging unit which is external to unit 10 but is connectable to power circuit 44, and other methods and battery recharging units as are known in the art.

Referring to FIG. 4, data network or circuit 76 is shown and, as is conventional with most data networks, includes LAN hub 74. LAN hub 74 shown in FIG. 4 may be, for example, a wireless LAN access point, such as an Aironet 350 Series access point (“AP”), available from Cisco Systems, Inc., of San Jose, Calif.; another suitable IEEE 802.11a or 802.11b compliant AP; a BlueEasy Bluetooth™ AP, available from Global PCS, Inc., of Hsinchu, Taiwan; another suitable IEEE 1394 compliant AP; an infrared (IR) AP; or any other wireless data device.

Alternatively, data network 76 may include a conventional network hub 74 also supporting wireless ports 78. In addition to wireless ports 78 and conventional network ports 36, unit 10 may include other data transfer ports such as USB ports 38, serial ports 68, parallel ports 70, personal computer memory card international association (“PCMCIA”) slots 72 for the receipt of PCMCIA or PC cards, or other standard data communication connections, thereby providing for a variety of data transfer ports for a variety of devices 61 and computers 54. Also, wireless handheld devices 82, such as cellular phones, personal data assistants (“PDAs”), etc., may be connected to hub 74 via a cabled connection or a wireless link, such as, for example, a Bluetooth™ link (www.bluetooth.com). As shown in FIG. 3, LAN hub 74 is mounted in interior compartment 60 of housing 22. LAN hub 74 is also connected to various ports located on front face 14, such as data ports 36 and USB ports 38. Additionally, LAN hub 74 may include antenna 75 for wireless communication and which may be located externally to cabinet 22, for example, extending from lid 20, as shown in FIG. 1.

Data network 76 may also be connected to WAN 77, such as, for example, the Internet. For example, LAN hub 74 may be connected to WAN 77 via a telecommunications network, cellular network, or a wireless protocol, such as Wi-Fi (www.weca.net) that is provided in a wireless Internet zone.

As can be seen in FIG. 4, data may be transferred both from hub 74 to the various ports and from the various ports to hub 74 to provide a complete data network structure 76 allowing data transfer between computer 54 and devices 61 connected to unit 10, or between multiple computers 54 connected to unit 10. Additionally, computers 54 and devices 61 may exchange data with WAN 77 through LAN hub 74.

With reference to FIG. 3, unit 10 is shown in an exemplary mobile office setting connected to laptop computer 54 and a plurality of handheld or peripheral devices 61, including, for example, fax machine 62, personal data assistant (“PDA”) 64, and printer 66. As shown, each of devices 61 may be selectively connected to electrical outlets 34, data ports 36, or USB ports 38, or any combination thereof. Although not shown in FIG. 3, devices 61 may also be connected to the other data transfer ports, such as serial ports 68, parallel ports 70, PCMCIA slots 72, and wireless ports 78, which are shown in FIG. 4. Through the connection of devices to these data transfer ports, data may be transferred between various devices 61, between computer 54 and devices 61, and between both computer 54 and devices 61 and WAN 77, through data network 76 (FIG. 4) of unit 10.

Unit 10 includes one or more batteries 46 therein and is therefore capable of being used in any location, whether wall outlets 58 (FIG. 3) are accessible or not. For example, unit 10 may be used to provide power and data connectivity in conference rooms, convention halls, or outdoors, and in automobiles, as the inclusion of wheels 28 and handle 26 provides mobility for unit 10. In addition to being used in a variety of locations to supply power to computer 54 and devices 61, data may be transferred between devices 61 connected to unit 10 through the various data transfer ports included within unit 10, thereby providing a mobile and self-contained electrical power and data transfer unit.

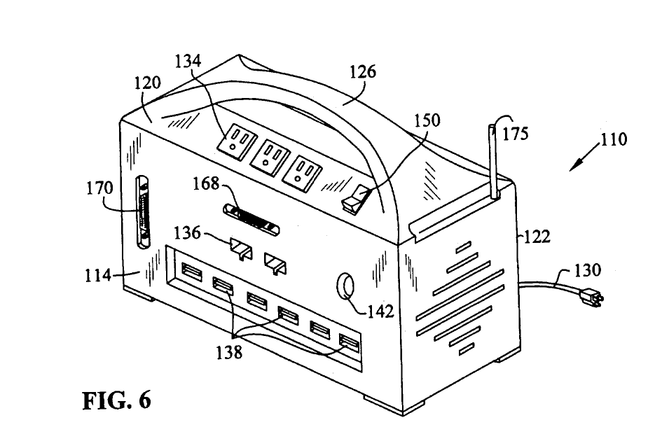

FIG. 6 shows a second exemplary embodiment of mobile data and electrical power unit 110. Unit 110 is sized for portable power and data applications requiring a smaller electrical power capacity, for example, to power a single computer and associated devices. Advantageously, housing 122 of unit 110 may be lightweight and of small size so that it may be carried by handle 126. Specifically, rechargeable battery 146 (not shown) may be of smaller size and weight because of the reduced capacity requirement than battery 46 of unit 10.

Hand portable unit 110 may include similar features as found in power circuit 44 and data network 76 of unit 10. Additionally, as shown in FIG. 6, front face 114 and top face 120 of housing 122 may include power and data connections such as, for example, AC power outlets 134, data ports 136, USB ports 138, DC outlet 142, serial port 168, and parallel port 170. Additionally, a switch 150 for controlling electric power provided to outlets 134 and 142 and a retractable power cord 130 for recharging battery 146 (not shown) may also be included. Housing 122 of unit 110 may also contain the various components of the data network and power circuits described above with reference to unit 10. Antenna 175 for wireless communication with unit 110 may also extend from and be retractable into a portion of housing 122.

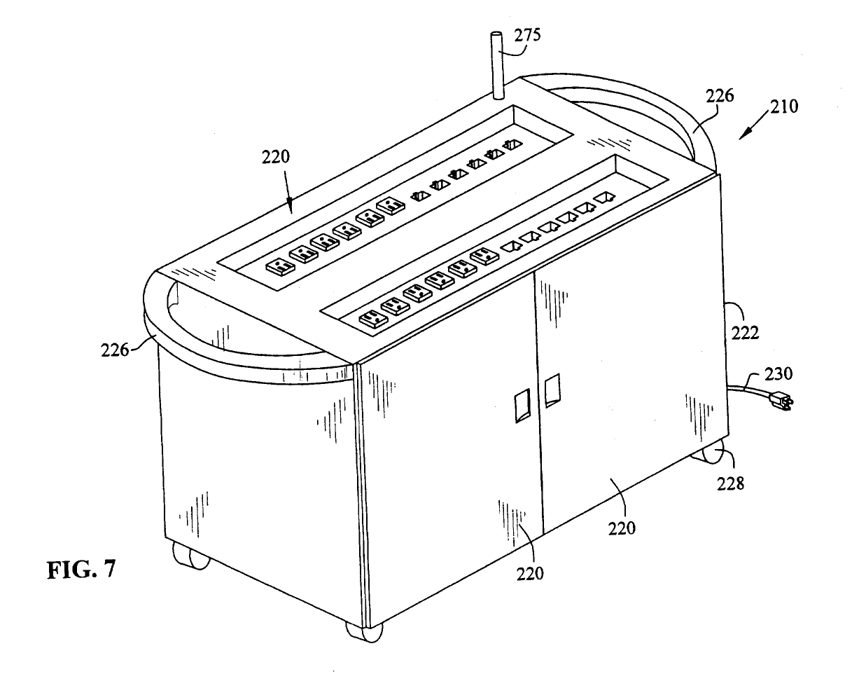

FIG. 7 shows a third exemplary embodiment of data and electrical power unit 210. Unit 210 is a larger unit than units 10 and 110 and includes push-pull cart 222 for storing batteries 246 (not shown) having a large power capacity for providing power to several computers and associated devices. Unit 210 may similarly include power and data circuits and connections as described above with reference to unit 10 and shown in FIGS. 2 and 3. As shown in FIG. 7, cart 222 includes doors 220 for accessing electrical and data components contained within cart 222, and handles 228 for moving unit 210 on wheels 228. Antenna 275 extends from cart 222 and provides for wireless communication with associated computers and devices. Additionally, top portion 220 of cart 222 includes a number of electrical power outlets 234, such as, for example, AC power outlets, and a number of data ports 236, such as, for example, USB ports. Unit 210 may alternatively include other housings and forms of mobility other than push-pull cart 222, for example, a small mobile utility vehicle having a built-in powered drive train for increased mobility for high weight, larger capacity applications.

The following are exemplary scenarios illustrating applications in which units 10, 110, and 210 may be used. However, such scenarios are exemplary only, and are intended merely as illustrations of some of the many potential uses for units 10, 110, and 210, and should not be construed as limiting the scope of the present invention in any manner. One of ordinary skill would recognize many other applications or ways in which units 10, 110, and 210 could be used.

In a first exemplary scenario, users of unit 10 of FIG. 3 may wheel unit 10 to a preferred place of use, which generally lacks AC power outlets 58 and/or data outlet 80; for example, a conference room that is not equipped for data processing. Upon placement of unit 10 in a selected area within the conference room, the users may proceed to connect power cables (not shown) from several computers 54 to AC outlets 34. The users may also connect computers 54 to data network 76 of unit 10 either by using data cables (not shown) plugged into data connections 36 or via wireless connections through antenna 75. Peripherals such as printer 66 may also be similarly connected to data network 76. Switching on power switch 50 (FIG. 2) of unit 10 will provide AC power to computers 54 and printer 66 and also provide DC power to any devices connected to DC outlets 42. Depending on the capacity of battery 46 and the power usage of data network 76, computers 54, and printer 66, unit 10 may provide data connections and power to the foregoing devices for a few hours, or with sufficient battery capacity, for a few days. Data network 76 may also provide connectivity with WAN 77, such as the Internet, or a building LAN (not shown). Typically, such connectivity between LAN 74 and another network may be most conveniently provided by a Wi-Fi or other wireless connection already available in the conference room or other area of use of unit 10. Thus, unit 10 provides data communication between computers 54 and another network, between computers 54 and printer 66, and between the several computers 54. When unit 10 is returned to a place having AC power outlet 58, retractable power cord 30 may be extended from cabinet 22 and plugged into AC power outlet 58, thereby recharging battery 46.

In a second exemplary scenario, a user of unit 110 of FIG. 6 may carry unit 110 by handle 126 to an outdoor location, such as a park, or other location lacking power or data connectivity. The user may utilize unit 110 to power a portable laptop computer and/or other data devices by plugging them into AC power outlets 134 or DC power outlet 142. Additionally, if the outdoor location is within a wireless Internet zone, such as those provided in increasing numbers by Wi-Fi wireless networks, antenna 175 may provide an Internet connect for a portable laptop computer by connecting a data cable of the computer into data port 136. Although unit 110 provides a smaller battery capacity than unit 10 or unit 210, the load of a single laptop computer or other data device may still be provided for a number of hours by battery 46 in housing 122.

While this invention has been described as having an exemplary structure, the present invention can be further modified within the spirit and scope of this disclosure. This application is therefore intended to cover any variations, uses, or adaptations of the invention using its general principles. Further, this application is intended to cover such departures from the present disclosure as come within known or customary practice in the art to which this invention pertains and which fall within the limits of the appended claims.

What is claimed is:

1. A portable data and electrical power unit, comprising:
a movable housing having at least one electrical receptacle and at least one data receptacle accessible from the exterior of said housing;
at least one rechargeable power source disposed within said housing, said electrical receptacle receiving electrical power from said rechargeable power source; and
at least one data transfer device disposed within said housing, said data transfer device being in communication with said data receptacle.

2. The portable data and electrical power unit of claim 1, wherein said rechargeable power source is a direct current (DC) source.

3. The portable data and electrical power unit of claim 1, wherein said rechargeable power source comprises at least one rechargeable battery.

4. The portable data and electrical power unit of claim 1, wherein said at least one electrical receptacle is an alternating current (AC) electrical outlet.

5. The portable data and electrical power unit of claim 4, further comprising a converter disposed within said housing, said converter converting power provided by said rechargeable power source to AC electrical power and supplying said power to said AC electrical outlet.

6. The portable data and electrical power unit of claim 5, wherein said converter is a DC to AC inverter.

7. The portable data and electrical power unit of claim 1, wherein said at least one electrical receptacle is a DC electrical outlet.

8. The portable data and electrical power unit of claim 1, further comprising a charging unit disposed within said housing, said charging unit adapted for noncontinuous recharging of said rechargeable power source.

9. The portable data and electrical power unit of claim 8, further including an electrical power cord electrically connected to said charger, said cord connectable to an external power source and movable between a first position in which said cord is retracted within said unit and a second position in which said cord is extended from said unit.

10. The portable data and electrical power unit of claim 1, wherein said at least one data receptacle is one of a data port, a universal serial bus port, a serial port, a parallel port, a Personal Computer Memory Card International Association (PCMCIA) slot, and a wireless port.

11. The portable data and electrical power unit of claim 1, wherein said data transfer device is a network hub, said network hub and said data receptacle comprising a data network.

12. The portable data and electrical power unit of claim 11, wherein said network hub is connectable to a wide area network (WAN) via a wireless data connection.

13. The portable data and electrical power unit of claim 11, wherein said network hub includes a wireless data connection adapted for communication with at least one of a computer, a peripheral device, and a handheld data appliance.

14. The portable data and electrical power unit of claim 1, wherein said data transfer device is adapted to transfer data between at least one of computers, peripheral devices, and handheld data appliances.

15. The portable data and electrical power unit of claim 1, wherein said data transfer device is adapted to transfer data between the Internet and at least one of a computer, a peripheral device, and a handheld data appliance.

16. The portable data and electrical power unit of claim 1, further comprising:
at least two wheels movably mounted to said housing; and
a handle extending from said housing.

17. A portable data and electrical power unit, comprising:
a movable housing having an exterior wall;
a handle connected to said housing;
at least one electrical receptacle and at least one data receptacle mounted within said exterior wall and accessible from the exterior of said housing;
at least one rechargeable power source disposed within said housing, said rechargeable power source electrically connected to each said electrical receptacle to supply electrical power thereto; and
at least one data transfer device disposed within said housing, said data transfer device in communication with said data receptacle.

18. The portable data and electrical power unit of claim 17, further comprising a charging unit disposed within said housing, said charging unit adapted for noncontinuous recharging of said rechargeable power source.

19. The portable data and electrical power unit of claim 17, wherein said at least one data receptacle is one of a data port, a universal serial bus port, a serial port, a parallel port, a Personal Computer Memory Card International Association (PCMCIA) slot, and a wireless port.

20. The portable data and electrical power unit of claim 17, wherein said data transfer device is a network hub, said network hub and said data receptacle comprising a data network.
